(19) United States
(12) Patent Application Publication
(10) Pub. No.: US 2003/0198311 A1
(43) Pub. Date: Oct. 23, 2003

(54) Fractional-N frequency synthesizer and method

(75) Inventors: Bang-Sup Song, La Jolla, CA (US); Chun Huat Heng, San Diego, CA (US)

Correspondence Address: KOPPEL, JACOBS, PATRICK & HEYBL, 555 ST. CHARLES DRIVE, SUITE 107, THOUSAND OAKS, CA, 91360, US

(73) Assignee: WIRELESS INTERFACE TECHNOLOGIES, INC.

(21) Appl. No.: 10/126,773

(22) Filed: Apr. 19, 2002

(51) Int. Cl. H03D 3/24

(52) U.S. Cl. 375/376; 327/156

(57) ABSTRACT

A fractional-N frequency synthesizer is based on a PLL which employs a multi-phase VCO and a multi-phase frequency divider to provide a desired fractional-N divider ratio. The multi-phase frequency divider includes a multi-modulus divider which divides a VCO output waveform with a division ratio that varies in response to a modulus control signal. The divided output is delayed to produce a plurality of outputs, each of which has a respective phase that corresponds with the phase of a respective VCO output. A phase selector provides a selected one of the outputs to the PLL's phase detector in response to a phase control signal such that the multi-phase frequency divider provides a fractional-N division ratio. To reduce fractional spurs, a modulator randomizes the modulus and phase control signals, which serves to randomize and thereby reduce phase mismatch error which might otherwise be present in the frequency synthesizer's output.

### BACKGROUND OF THE INVENTION

1. Field of the Invention

This invention relates to the field of fractional-N synthesizers, and particularly to techniques for randomizing phase mismatch for a fractional-N synthesizer which uses a multi-phase VCO.

2. Description of the Related Art

In an RF transceiver, local carrier frequencies are used to modulate transmitted signals and to demodulate received signals. A common way to generate local carrier frequencies is to use frequency synthesizers which are based on phase-locked-loop (PLL) circuits. A basic frequency synthesizer inserts a frequency divider between the PLL's voltage-controlled oscillator (VCO) and its phase detector (PD); the divider divides the VCO output by an integer value N. When this divided down signal is provided to the PD along with a reference frequency f_{ref}, the frequency of the VCO's output signal is given by f_{ref}*N. By changing N, the synthesizer can generate frequencies which are an integer multiple of f_{ref}.

This approach has several drawbacks, however. For this type of “integer-N” frequency synthesizer, the channel spacing—i.e., the minimum spacing between frequencies which the synthesizer is capable of generating—is equal to f_{ref}, which is typically very low. Furthermore, such a synthesizer cannot effectively suppress high-frequency VCO phase noise. This is because a PLL can only suppress VCO phase noise within its bandwidth, which is typically 1/10 to 1/20 of f_{ref}. Thus, VCO phase noise at frequencies higher than f_{ref}/10 or f_{ref}/20 cannot be suppressed.

A “fractional-N” frequency synthesizer provides an alternative means for achieving a desired channel spacing. Here, the division ratio of the frequency divider inserted between the VCO and the PD can be a fraction, instead of being limited to an integer. This enables desired channel spacing to be achieved with a higher reference frequency. A higher f_{ref} value results in a higher PLL bandwidth, which enables VCO phase noise at higher frequencies to be suppressed.

Unfortunately, fractional-N frequency synthesizers exhibit a number of problems. To obtain a fractional ratio, the VCO waveform is divided by one integer value during a first time interval, and by an adjacent integer value during a second time interval; the effect of the two division ratios is filtered out with the PLL's loop filter, and the VCO follows the average frequency. However, when the desired fractional division ratio approaches an integer value, one division ratio is employed for a much longer interval than is the other ratio. This can result in the synthesizer exhibiting low-frequency fractional spurs, which can degrade synthesizer performance.

One way of reducing low-frequency fractional spurs in a fractional-N frequency synthesizer is to use a modulator to randomize the division ratio, while maintaining the desired fractional division ratio over the long term. However, the minimum phase resolution for such a synthesizer is limited to the period of the VCO's output frequency, as is the case for a conventional integer-N synthesizer. Phase resolution can be improved with the use of a multi-phase VCO. Here, the VCO provides a number of outputs, each with a common frequency but having different phases with respect to each other. Fractional-N division ratios are achieved by switching different VCO output phases to the divider over time; the phases are thus interpolated, making possible finer phase resolution. Unfortunately, if the VCO output phases are not equally spaced, this “phase mismatch” error may also result in the production of performance-degrading fractional spurs. Conventional synthesizer designs also exhibit limited frequency resolution.

### SUMMARY OF THE INVENTION

A fractional-N frequency synthesizer is presented which overcomes the problems noted above, providing fine phase resolution while reducing the occurrence of low-frequency fractional spurs.

The present frequency synthesizer is based on a PLL which employs a multi-phase VCO and a multi-phase frequency divider to provide a desired fractional-N divider ratio. The multi-phase frequency divider includes a programmable multi-modulus divider which divides one of the VCO output waveforms with a multi-modulus division ratio which varies in response to a modulus control signal. The multi-modulus divider output is delayed to produce a plurality of divided outputs, each of which has a respective phase which corresponds with the phase of a respective one of the VCO output waveforms. A phase selector provides a selected one of the divided outputs to the phase detector in response to a phase control signal such that the multi-phase frequency divider provides a fractional-N division ratio. A controller provides the modulus control and phase control signals needed to achieve a desired fractional-N division ratio.

To reduce fractional spurs, a modulator—preferably a ΔΣ modulator—is employed to randomize the modulus and phase control signals produced by the controller, which serves to randomize and thereby reduce phase mismatch error which might otherwise be present in the frequency synthesizer's output. This also enables the synthesis of frequencies with finer resolution than would be possible without the use of the modulator.

Further features and advantages of the invention will be apparent to those skilled in the art from the following detailed description, taken together with the accompanying drawings.

### BRIEF DESCRIPTION OF THE DRAWINGS

FIG. 1 is a block diagram of a fractional-N frequency synthesizer in accordance with the present invention.

FIG. 2 is a graph illustrating how phases applied to a frequency synthesizer's phase detector might be divided for various synthesizer configurations.

FIG. 3 is a block diagram of a multi-phase VCO in accordance with the present invention.

FIG. 4 is a block diagram of a multi-phase frequency divider as might be used with the present invention.

FIG. 5 is a block diagram of a multi-modulus divider, a controller, and a modulator as might be used with the present invention.

### DETAILED DESCRIPTION OF THE INVENTION

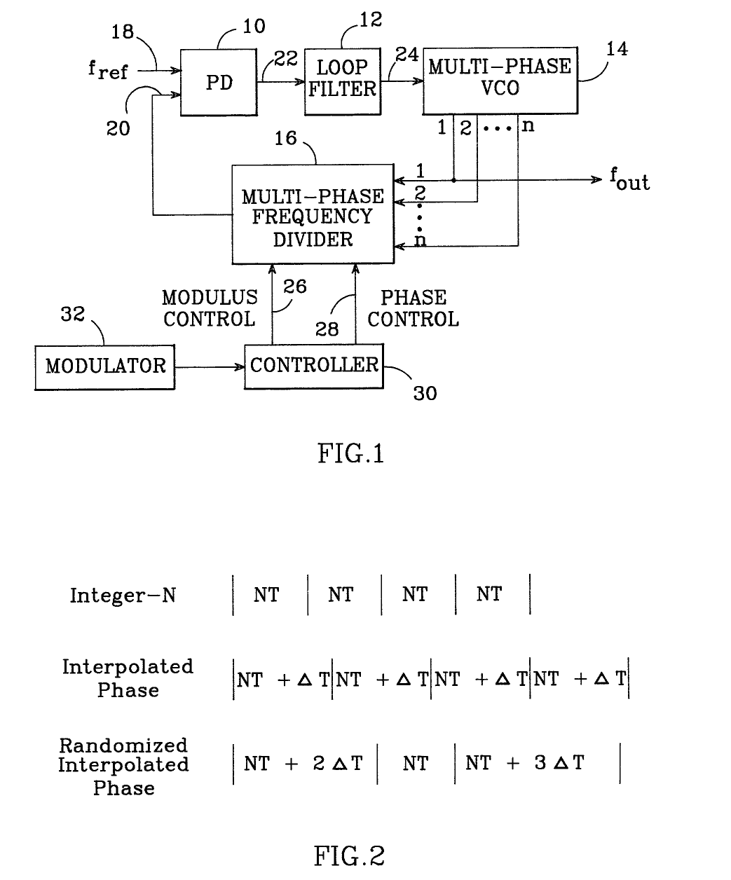

A fractional-N frequency synthesizer in accordance with the present invention is shown in FIG. 1. The synthesizer is based on a PLL. As with a conventional PLL, the synthesizer include a phase detector (PD) 10, a loop filter 12, a VCO 14, and a frequency divider 16. Phase detector 10 receives a reference frequency f_{ref} at an input 18 and the output of frequency divider 16 at an input 20. Phase detector 10 produces an output 22 which varies with the phase difference between the signals presented at its inputs. Phase detector output 22 is filtered with loop filter 12, which produces a voltage output 24 which varies with the magnitude of the phase difference detected by phase detector 10.

The voltage output 24 of loop filter 12 is provided to the input of VCO 14. VCO 14 is a multi-phase VCO; i.e., the VCO produces ‘n’ outputs which have a common frequency f_{vco} which varies with voltage output 24, but which have respective phases that differ from each other. For example, if VCO 14 is a 4-phase VCO (n=4), and the period of common frequency f_{vco} is T, then VCO 14 has four outputs, each of which is time-shifted by T/4. Thus, the four outputs have rising edges that occur at times T/4, T/2, 3T/4, and T, and each VCO output toggles at frequency f_{vco}.

The n outputs of VCO 14 are provided to multi-phase frequency divider 16. Divider 16 divides down a selected one of the VCO outputs with a programmable multi-modulus divider, and then delays the multi-modulus divider output with each of the VCO output phases to produce a plurality of divided down outputs, each of which corresponds to a VCO output phase. One of the divided down output phases is selected and fed to the second input 20 of phase detector 10 to close the loop. The multi-modulus division ratio is controlled with a “modulus control” signal 26, and the divided down output phase selection is controlled with a “phase control” signal 28, each of which is provided by a controller 30. The multi-modulus division ratio and the phase selection are adjusted as necessary to achieve a desired fractional-N division ratio. When so arranged, the present frequency synthesizer produces an output fₒᵤₜ, which is taken at one or more of the VCO outputs and which may be a non-integer multiple of reference frequency f_{ref}.

To reduce low-frequency fractional spurs, the fractional-N frequency synthesizer uses a modulator 32 to randomize the multi-modulus division ratio (via the modulus control signal) and the phase selection (via the phase control signal), while maintaining the desired fractional division ratio over the long term. This serves to randomize the phase mismatch error and eliminate the fixed pattern noise that might otherwise be present in the fractional-N frequency synthesizer's output. The present invention also enables the synthesis of frequencies with finer resolution than would be possible without the use of the modulator. The modulator is preferably a high-order digital ΔΣ modulator such as a MASH or multi-bit ΔΣ modulator, though other modulators—such as a modulator which employs the Wheatley randomization method without noise shaping—could also be used.

The effect of the present invention is illustrated in the graph shown in FIG. 2, where the horizontal axis is time and the divided phases applied to the PLL's phase detector are shown in units of the VCO period T. The top line of the graph applies to a conventional integer-N frequency synthesizer, for which the minimum incremental step in the divided period is an integer multiple of VCO period T (NT). When a multi-phase VCO is employed (middle line of graph), a constant fraction of the VCO period, referred to here as ΔT, can be added to NT to generate a constant period. However, when a frequency synthesizer is configured in accordance with the present invention, the periods of the divided phases applied to the phase detector are randomized (bottom line of graph), as is the phase mismatch.

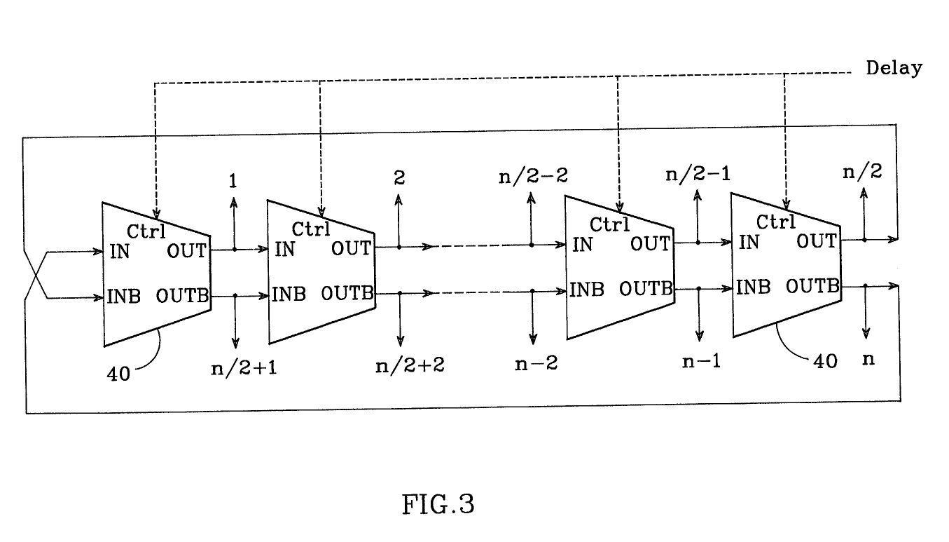

Multi-phase VCO 14 may be implemented in any number of ways; one possible configuration is shown in FIG. 3. Here, n output phases are generated with n/2 differential delay cells 40 connected in a ring oscillator configuration. Each delay cell receives a “delay” signal which adjusts the delay imposed by each cell.

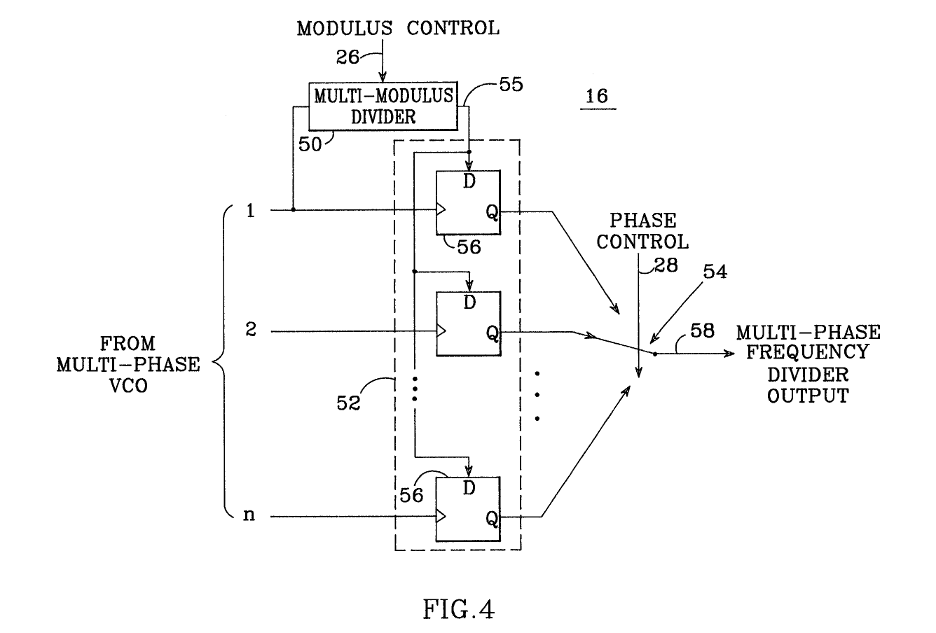

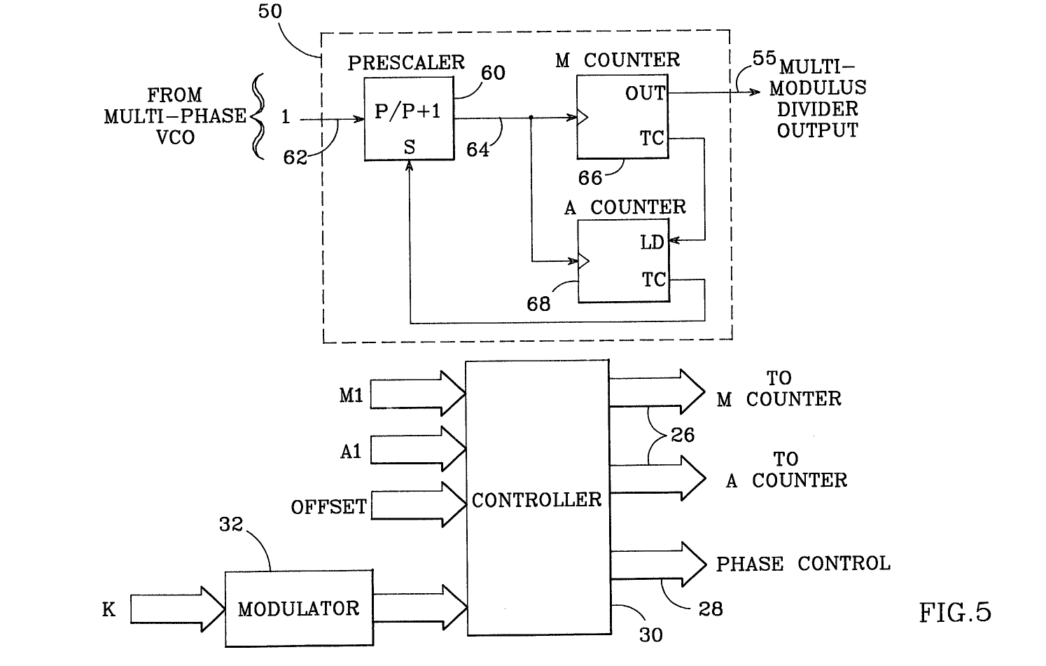

An exemplary multi-phase frequency divider 16 is shown in FIG. 4. Divider 16 preferably includes a programmable multi-modulus divider 50, a means 52 for delaying the output of the multi-modulus divider using the VCO output phases, and a phase select switch 54. Multi-modulus divider 50 is arranged to divide down one of the VCO outputs, for example, phase 1 (as shown in FIG. 4), with a multi-modulus division ratio which is controlled with modulus control signal 26; the divided down signal is provided at an output 55. In response to modulus control signal 26, multi-modulus divider 50 divides the VCO output randomly by N, N+1, N+2 or N+3 over respective time intervals, with N defined by the user.

The delaying means 52 preferably comprises an array of n dynamic D-latches 56, each of which receives the output 55 of multi-modulus divider 50 at its D input. Each D-latch 56 is clocked with a respective one of the n output phases produced by multi-phase VCO 14. The D-latches 56 thus delay the multi-modulus divider output using the different VCO phases, and thus produce n outputs at the latches' respective Q outputs—with each output having a phase which corresponds to a respective one of the VCO output phases.

The n delayed multi-modulus divider outputs are provided to phase select switch 54. In response to phase control signal 28, one of the delayed outputs is selected as the multi-phase frequency divider output 58, which is provided to input 20 of phase detector 10—thereby closing the loop. By properly controlling the multi-modulus divider and the phase select switch, a desired fractional-N division ratio—and thus a desired output frequency fₒᵤₜ, is achieved. When the synthesizer is configured as described above, the fractional-N division ratio DR provided by multi-phase frequency divider 16 is given by:

DR=(X+Y)−Z,

where X is equal to the multi-modulus division ratio, Y is equal to the current phase, and Z is equal to the previous phase.

One possible embodiment of multi-modulus divider 50 is shown in FIG. 5, which also includes controller 30 and modulator 32. Multi-modulus divider 50 preferably includes a prescaler 60, which receives one of the VCO outputs at its input 62 and which divides the input signal by either P or P+1, depending on the state of an input S; the divided signal is provided at the prescaler's output 64. For example, if prescaler 60 is a “⅘” prescaler, it divides the incoming signal by 4 if S=1 and by 5 if S=0. The input to the prescaler may be phase 1 from VCO 14 (as shown in FIG. 5), or may be one of the other VCO outputs.

Prescaler output 64 is used to clock two counters: an M counter 66 and an A counter 68. The M counter counts from 0 up to a maximum value M, toggles its terminal count output TC, and resumes counting from 0. The A counter loads a value A when the TC output of the M counter toggles. The A counter counts down to zero, where it stops and toggles its TC output. The next time the M counter's TC output toggles, the A counter reloads the A value and starts counting down, and the process repeats. The TC output of the A counter is connected to the prescaler's S input. The M counter has an output OUT which toggles at the same frequency as its TC output, but which has a duty cycle of approximately 50%. This output provides the multi-modulus divider's output 55. When so arranged, multi-modulus divider 50 provides a division ratio of PM+A, where P is the prescaler division ratio and M and A are the M and A values loaded into the M and A counters, respectively.

Values M and A constitute modulus control signal 26, and are produced by controller 30. Controller 30 receives user-settable values M1 and A1 as inputs, which establish the value of N in the multi-modulus divider's division ratio. As noted above, the modulus control signal—i.e., the M and A values—are randomized using modulator 32.

Controller 30 also provides phase control signal 28, which causes phase control switch 54 to select one of the delayed multi-modulus divider outputs to pass on to phase detector 10. As with the modulus control signal, the phase control signal is randomized using modulator 32. When both the modulus control and phase control signals are randomized as described herein, low-frequency fractional spurs which might otherwise be present in the synthesizer's output are reduced.

Adjusting the M and A values provides coarse control of the range over which the fractional-N division ratio can be generated. Fine frequency resolution is provided by an input K to modulator 32. The K value is a user setting, which is randomized by modulator 32 to provide fine control of the fractional-N division ratio. For example, M1 and A1 values can be selected to provide a range of division ratios between N+6/4 and N+7/4. Then, adjusting the K value enables an actual division ratio within this range, such as N+6/4+0.1 or N+6/4+0.135, to be achieved.

To cover a wider frequency range, an OFFSET value is preferably added to the M, A and phase control values. When so arranged, the effective multi-modulus division ratio is given by:

(P*M)+A+(OFFSET/n)+[K/(n*2^{r})],

where n is the number of VCO output phases and 2^{r} is the smallest achievable phase resolution. The effect of the offset value is illustrated as follows. Assume that without the use of an offset value, the multi-phase frequency divider can provide multi-modulus division ratios of N, N+1/4, N+2/4, N+3/4, N+1, N+5/4, N+6/4, N+7/4, N+2, N+9/4, N+10/4, N+11/4, and N+3. Using the AZ modulator, division ratios between N+6/4 and N+7/4 (for example) can be achieved. Changing an M1 or A1 value causes the ratios to jump, so that the achievable ratios become (e.g.) N+1, N+5/4, N+6/4, N+7/4, N+2, N+9/4, N+10/4, N+11/4, N+3, N+13/4, N+14/4, N+15/4, and N+4. Now, using the ΔΣ modulator, only division ratios between N+10/4 and N+11/4 can be achieved. Thus, for this example, division ratios between N+7/4 and N+10/4 cannot be achieved by simply changing the M1 and A1 values provided to controller 30. However, by providing an offset value, the division ratios can start at a fractional value. For example, if OFFSET=1, the achievable ratios become N+1/4, N+2/4, N+3/4, N+1, N+5/4,N+6/4, N+7/4, N+2, N+9/4, N+10/4, N+11/4, N+3 and N+13/4. This allows division ratios between N+7/4 and N+2 to be covered. Changing the offset value allows other division ratios to be covered.

Use of an offset value is preferred: without the use of offset and the modulator, synthesized frequency resolution is limited to (1/n)*f_{ref}. However, with the randomization of K and the use of an offset value, interpolated phase errors can be shaped and moved to higher frequencies. Furthermore, finer frequency resolution is made possible because the division ratio is now an average division ratio rather than a fixed division ratio.

Controller 30 is suitably implemented with combinational logic. The controller logic is designed to combine the M1, A1, OFFSET, and modulator signals as necessary to provide the necessary modulus control and phase control signals.

To lower the speed requirement of the M and A counters, a prescaler with a higher division ratio of 5/6 is preferred over the more commonly used 4/5 prescaler.

While particular embodiments of the invention have been shown and described, numerous variations and alternate embodiments will occur to those skilled in the art. Accordingly, it is intended that the invention be limited only in terms of the appended claims.

I claim:

1. A fractional-N frequency synthesizer, comprising:
a phase-locked-loop (PLL) circuit comprising:
a phase detector having a first input connected to receive a reference frequency and a second input and which produces an output which varies with the phase difference between the signals received at said first and second inputs,
a loop filter which filters said phase detector output,
a multi-phase voltage-controlled oscillator (VCO) which receives said filtered phase detector output and outputs a plurality of waveforms having a common frequency which varies with said filtered phase detector output, the phases of said plurality of VCO output waveforms differing with respect to each other, at least one of said plurality of VCO output waveforms providing said fractional-N frequency synthesizer's output, and
a multi-phase frequency divider which comprises:
a programmable multi-modulus divider which divides a selected one of said plurality of VCO waveforms with a multi-modulus division ratio which varies in response to a modulus control signal and provides said divided waveform at an output,
a means for delaying said multi-modulus divider output to produce a plurality of divided outputs having respective phases, each of which corresponds with a respective one of said VCO output phases, and
a phase selector which provides a selected one of said divided outputs to the second input of said phase detector in response to a phase control signal such that said multi-phase frequency divider provides a fractional-N division ratio,
a controller which provides said modulus control signal and said phase control signal to achieve a desired fractional-N division ratio, and
a modulator arranged to randomize the modulus and phase control signals produced by said controller to randomize and thereby reduce phase mismatch error which might otherwise be present in said fractional-N frequency synthesizer's output and to enable the synthesis of frequencies with finer resolution than would be possible without the use of said modulator.

2. The frequency synthesizer of claim 1, wherein said modulator is a ΔΣ modulator.

3. The frequency synthesizer of claim 1, wherein said a multi-phase VCO is a ring oscillator comprising a plurality of differential delay cells connected in a ring configuration.

4. The frequency synthesizer of claim 1, wherein the programmable multi-modulus divider comprises:
a prescaler which receives said selected VCO waveform and divides it by a prescaler division ratio P which varies in response to a control signal S,
a first counter which is clocked by the output of said prescaler, is arranged to toggle an output TC upon counting to a predetermined maximum value M, and which has an output OUT which toggles at the same frequency as said TC output and has a duty cycle of approximately 50%, said output OUT providing said multi-modulus divider output, and
a second counter which is clocked by the output of said prescaler and is arranged to load a start value A when said first counter's TC output toggles and to toggle an output TC upon counting down to zero, said second counter's TC value providing said control signal S to said prescaler, said M and A values provided by said controller as said randomized modulus control signal,
such that the frequency of said output OUT is equal to that of said selected VCO output divided by a multi-modulus division ratio given by (P*M)+A.

5. The frequency synthesizer of claim 4, wherein said prescaler is a ⅚ prescaler.

6. The frequency synthesizer of claim 4, wherein said modulator is a ΔΣ modulator which randomizes an input K, further comprising an offset value OFF which is added to said M, A and phase control values such that the effective multi-modulus division ratio is given by (P*M)+A+(OFF/n)+[K/(n*2^{r})], where n is the number of phases produced by said multi-phase VCO and 2^{r} is the smallest achievable phase resolution.

7. The frequency synthesizer of claim 1, wherein said means for delaying said multi-modulus divider output comprises a plurality of latches, each of which latches said multi-modulus divider output in response to a respective one of said plurality of VCO output waveforms, the outputs of said latches providing said divided outputs having respective phases, each of which corresponds with a respective one of said VCO output phases.

8. The frequency synthesizer of claim 7, wherein said plurality of latches comprise respective D-latches, each of which receives said multi-modulus divider output at its D input and a respective one of said plurality of VCO output waveforms at its clock input and which produces a respective one of said plurality of divided outputs at its Q output.

9. The frequency synthesizer of claim 1, wherein said multi-phase frequency divider is arranged to provide a fractional-N division ratio (DR) which is given by:
DR=(X+Y)−Z,
where X is equal to the multi-modulus division ratio, Y is equal to the current phase, and Z is equal to the previous phase.

10. A fractional-N frequency synthesizer, comprising:
a phase-locked-loop (PLL) circuit comprising:
a phase detector having a first input connected to receive a reference frequency and a second input and which produces an output which varies with the phase difference between the signals received at said first and second inputs,
a loop filter which filters said phase detector output,
a multi-phase voltage-controlled oscillator (VCO) which receives said filtered phase detector output and outputs a plurality of waveforms having a common frequency which varies with said filtered phase detector output, the phases of said plurality of VCO output waveforms differing with respect to each other, at least one of said plurality of VCO output waveforms providing said fractional-N frequency synthesizer's output, and a multi-phase frequency divider which comprises:
a programmable multi-modulus divider which divides a selected one of said plurality of VCO waveforms with a multi-modulus division ratio which varies in response to a modulus control signal and provides said divided waveform at an output,
a plurality of D-latches, each of which receives said multi-modulus divider output at its D input and a respective one of said plurality of VCO output waveforms at its clock input and which produce a plurality of delayed multi-modulus divider outputs at their respective Q outputs, each of said delayed multi-modulus divider outputs having respective phases, each of which corresponds with a respective one of said VCO output phases, and
a phase selector which provides a selected one of said latch outputs to the second input of said phase detector in response to a phase control signal such that said multi-phase frequency divider provides a fractional-N division ratio,
a controller which provides said modulus control signal and said phase control signal to achieve a desired fractional-N division ratio (DR) which is given by:
DR=(x+Y)−Z,
where X is equal to the multi-modulus division ratio, Y is equal to the current phase, and Z is equal to the previous phase, and
a ΔΣ modulator arranged to randomize the modulus and phase control signals produced by said controller to randomize and thereby reduce phase mismatch error which might otherwise be present in said fractional-N frequency synthesizer's output and to enable the synthesis of frequencies with finer resolution than would be possible without the use of said modulator.

11. The frequency synthesizer of claim 10, wherein said programmable multi-modulus divider comprises:
a prescaler which receives said selected VCO waveform and divides it by a prescaler division ratio P which varies in response to a control signal S,
a first counter which is clocked by the output of said prescaler, is arranged to toggle an output TC upon counting to a predetermined maximum value M, and which has an output OUT which toggles at the same frequency as said TC output and has a duty cycle of approximately 50%, said output OUT providing said multi-modulus divider output, and
a second counter which is clocked by the output of said prescaler and is arranged to load a start value A when said first counter's TC output toggles and to toggle an output TC upon counting to a maximum count value, said second counter's TC value providing said control signal S to said prescaler, said M and A values provided by said controller as said randomized modulus control signal,
such that the frequency of said output OUT is equal to that of said selected VCO output divided by a multi-modulus division ratio given by (P*M)+A.

12. The frequency synthesizer of claim 11, wherein said ΔΣ modulator randomizes an input K, further comprising an offset value OFF which is added to said M, A and phase control values such that the effective multi-modulus division ratio is given by (P*M)+A+(OFF/n)+[K/(n*2^{r})], where n is the number of phases produced by said multi-phase VCO and 2^{r} is the smallest achievable phase resolution.

13. A method of synthesizing a frequency, comprising:
generating a first output which varies with the phase difference between a reference signal and a second signal,
generating a plurality of oscillating waveforms, each of which has a common frequency that varies with said first output, said oscillating waveforms having phases which differ with respect to each other, at least one of said oscillating waveforms being the synthesized frequency output,
dividing down a respective one of said oscillating waveforms with a multi-modulus division ratio which varies in response to a modulus control signal, delaying said divided down output to produce a
plurality of divided outputs having respective phases, each of said which corresponds with a respective one of said phases of said oscillating waveforms,
selecting a respective one of said divided outputs in response to a phase control signal, said selected divided output being said second signal,
providing said modulus control signal and said phase control signal such that the frequency of said second signal is equal to that of said common frequency divided down with a desired fractional-N division ratio, and
randomizing said modulus and phase control signals to randomize and thereby reduce phase mismatch error which might otherwise be present in said synthesized frequency output and to enable the synthesis of frequencies with finer resolution than would be possible without the use of said randomization.

14. The method of claim 13, wherein said randomization is provided by a ΔΣ modulator.
